(19) United States
(12) Patent Application Publication
(10) Pub. No.: US 2021/0336086 A1
(43) Pub. Date: Oct. 28, 2021

(54) SURFACE LIGHT SOURCE CHIP AND LIGHT EMITTING DIODE THEREOF

(71) Applicant: Wuhan China Star Optoelectronics Technology Co., LTD, Hubei (CN)

(72) Inventor: Yong YANG, Hubei (CN)

(73) Assignee: Wuhan China Star Optoelectronics Technology Co., Ltd., Hubei (CN)

(21) Appl. No.: 16/485,434

(22) PCT Filed: Apr. 23, 2019
(86) PCT No.: PCT/CN2019/083915

§ 371 Date: Aug. 12, 2019

(30) Foreign Application Priority Data
Nov. 30, 2018 (CN) 201811458791.7

(51) Int. Cl. H01L 33/32; H01L 33/06; H01L 33/46; H01L 33/62; H01L 33/48; H01L 33/38

(52) U.S. Cl. CPC H01L 33/32; H01L 33/06; H01L 33/38; H01L 33/62; H01L 33/486; H01L 33/46

(57) ABSTRACT

A surface light source and a light emitting diode thereof are provided. The surface light source chip includes a sapphire substrate, an N-type GaN buffer layer under the sapphire substrate, and a chip positive electrode area and a chip negative electrode area formed under the N-type GaN buffer layer, wherein the chip positive electrode area includes an N-type GaN layer, a multiple quantum well (MQW) emitting layer, an omni-directional reflector (ODR) layer and a chip positive electrode from top to bottom sequentially, and the chip negative electrode area includes a chip negative electrode. The light emitting diode includes the surface light source chips mentioned above.

### FIELD OF INVENTION

The present disclosure relates to the field of light emitting diode technology, particularly to a surface light source and a light emitting diode thereof.

### BACKGROUND OF INVENTION

With development of the commercial display splicing technology and consumer increase of the appearance to the liquid crystal display televisions (LCD TVs), a super narrow bezel mini light emitting diode (mini-LED), also called sub-millimeter light emitting diode or a surface light source, which is used as the next generation display technology and is thought to have bright prospects by many LED industry chain enterprises. It has many advantages such as flexible bendability, low power consumption, high brightness, high dynamic contrast and narrow bezels, and so on and is favored by most manufacturers. However, optical performance of mini-LEDs also faces some problems that need to be overcome, such as low light extraction efficiency, non-uniformity of color mixing, high cost, and so on, so this troubles the industry all the time. Due to controlling costs requirements, the surface light source needs as few chips as possible to realize the normal backlight brightness display, however the increase of the pitch between the adjacent chips can bring the non-uniformity of color mixing. Commonly used chip membrane layer structure most apply distributed Bragg reflection layer (DBR layer), but a light reflection on the reflection layer has an angle directionality, and the intensity of the reflected light at the large visual angle direction is weak, thereby causing non-uniformity color mixing, and people have no better solution for this now.

### SUMMARY OF INVENTION

In order to solve the weak intensity of the reflected light on the large visual angle direction which causes the non-uniformity of color mixing in distributed Bragg reflector (DBR) layer of the membrane layer structure, the present disclosure through application of omni-directional reflector (ODR) layer on a surface light source chip to replace the DBR layer, and making the light intensity of the chip distributes more uniformly in the range of a light extraction angle and increase the overall uniformity of color mixing of the whole face of the surface light source.

To realize the above-mentioned purpose, the present disclosure applies the technical solutions as follows:

In an embodiment of the present disclosure, providing a surface light source chip which includes a sapphire substrate, an N-type GaN buffer layer under the sapphire substrate, and a chip positive electrode area and a chip negative electrode area formed under the N-type GaN buffer layer, wherein the chip positive electrode area includes an N-type GaN layer, an multiple quantum well (MQW) light emitting layer, an omni-directional reflector (ODR) layer and a chip positive electrode arranged from top to bottom sequentially, and the chip negative electrode area includes a chip negative electrode.

Further, wherein the ODR layer includes a semiconductor material layer, a refracting layer, and a metal layer arranged from top to bottom sequentially.

Further, wherein the semiconductor material layer is a GaN layer.

Further, wherein the refracting layer is an indium tin oxide (ITO) layer or a microporous oxide thin film. The smaller the refractive index it is, the deflection of the refracted light is smaller, so selecting the material with a low refractive index be as refracting layer.

Further, wherein a thickness of the refracting layer satisfies λ/(4n), wherein A is a wavelength and n is a refractive index of the refracting layer.

Further, wherein the metal layer is electrically conductive material, including an alloy of gold and nickel or a silver metal.

Further, wherein under the chip positive electrode is a positive metal electrode pad, and under the chip negative electrode is a negative metal electrode pad.

In another embodiment of the present disclosure, providing a light emitting diode, which includes the surface light source chips as mentioned above.

Further, wherein the light emitting diode further includes substrate and a fluorescent thin film. The substrate which is used to carry the surface light source chips, and the fluorescent thin film covers the substrate and the surface light source chips.

Further, wherein the surface light source chips are disposed on the substrate with an equal spacing there among.

Different from the prior art, the present disclosure through application of an omni-directional reflector (ODR) layer on a surface light source chip to replace the distributed Bragg reflector (DBR) layer, and making the light intensity of the chip distributes more uniformly in the range of a light extraction angle and increase the overall uniformity of color mixing of the whole face of the surface light source.

Meanwhile, most of the DBR layer is constituted by insulation materials, which conductive performance and heat emission performance are poor, making the surface light source chip easy to occur a light saturation phenomena under large electric current condition. Compared to the DBR layer, the ODR layer has a higher reflectivity, and meanwhile the reflectivity does not change with an incident angle, thereby avoiding the problem of the low reflectivity of a short wavelength under the condition for approaching positive visual angle, and the problem causes the decrease of the light efficiency under a facing condition and influences the uniformity of chromaticity in angle ranges.

### DESCRIPTION OF DRAWINGS

FIG. 1 is a structural schematic diagram of a surface light source chip of an embodiment of the present disclosure.

FIG. 2 is a structural schematic diagram of a light emitting diode of an embodiment of the present disclosure.

### DETAILED DESCRIPTION OF PREFERRED EMBODIMENTS

In the present disclosure, unless expressly specified or limited otherwise, a first feature is “on” or “beneath” a second feature may include that the first feature directly contacts the second feature and may also include that the first feature does not directly contact the second feature. Furthermore, a first feature “on,” “above,” or “on top of” a second feature may include an embodiment in which the first feature is right “on,” “above,” or “on top of” the second feature and may also include that the first feature is not right “on,” “above,” or “on top of” the second feature, or just means that the first feature has a sea level elevation greater than the sea level elevation of the second feature. While first feature “beneath,” “below,” or “on bottom of” a second feature may include that the first feature is “beneath,” “below,” or “on bottom of” the second feature and may also include that the first feature is not right “beneath,” “below,” or “on bottom of” the second feature, or just means that the first feature has a sea level elevation less than the sea level elevation of the second feature.

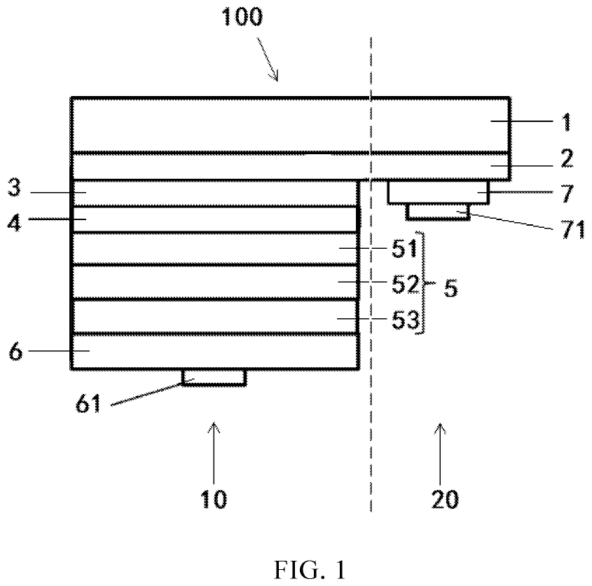

Please refer to FIG. 1, where in an embodiment of the present disclosure, provides a surface light source chip 100 which includes a sapphire substrate 1, an N-type GaN buffer layer 2 under the sapphire substrate 1, and a chip positive electrode area 10 and a chip negative electrode area 20 formed under the N-type GaN buffer layer 2, wherein the chip positive electrode area 10 includes an N-type GaN layer 3, an multiple quantum well (MQW) emitting layer 4, an omni-directional reflector (ODR) layer 5 and a chip positive electrode 6 from top to bottom sequentially, and the chip negative electrode area 20 includes a chip negative electrode 7.

Wherein the ODR layer 5 includes a semiconductor material layer 51, a refracting layer 52 and a metal layer 53 arranged from top to bottom sequentially.

Wherein the semiconductor material layer 51 is a GaN layer. GaN material is with a series of advantages such as wide band gap, high electron mobility, high thermal conductivity, high stability, and so on.

Wherein the refracting layer is an indium tin oxide (ITO) layer or a microporous oxide thin film. The smaller the refractive index it is, the deflection of the refracted light is smaller, so selecting the material with a low refractive index be as refracting layer 52.

Wherein a thickness of the refracting layer 52 satisfies λ/(4n), wherein A is a wavelength and n is a refractive index of the refracting layer 52.

Wherein the metal layer 53 is an electrically conductive material, including an alloy of gold and nickel or a silver metal, preferably silver metal, which is a high reflecting metal for forming the ODR structure and increases the brightness of the chip.

Wherein under the chip positive electrode 6 is a positive metal electrode pad 61, and under the chip negative electrode 7 is a negative metal electrode pad 71.

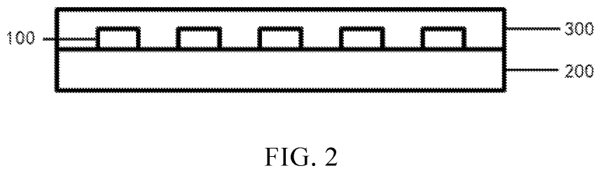

Please refer to FIG. 2, where in another embodiment of the present disclosure, providing a light emitting diode, which includes the surface light source chips 100 as mentioned above.

Wherein the light emitting diode further includes substrate 200 and a fluorescent thin film 300. The substrate 200 which is used to carry the surface light source chips 100, and the fluorescent thin film 300 covers the substrate 200 and the surface light source chips 100. The fluorescent thin film 300 can be a packaging adhesive form, such as a packaging adhesive which is mixed with fluorescent powder.

Wherein the surface light source chips 100 are disposed on the substrate 200 with an equal spacing there among.

Different from the prior art, the present disclosure through application of an ODR layer on a surface light source chip to replace the DBR layer, and making the light intensity of the chip distributes more uniformly in the range of a light extraction angle and increase the overall uniformity of color mixing of the whole face of the surface light source, thereby ensure the surface light source has great effect of color mixing and high luminous efficacy.

Meanwhile, most of the DBR layer is constituted by insulation material, which conductive performance and heat emission performance are poor, making the surface light source chip easy to occur a light saturation phenomena under large electric current condition. Compared to the DBR layer, the ODR layer has a high reflectivity, and meanwhile the reflectivity does not change with an incidence angle, thereby avoiding the problem of the low reflectivity of short wavelength under the condition for approaching positive visual angle which causes the decrease of the light efficiency under a facing condition and influences uniformity in angle ranges.

Which mentioned above is preferred embodiments of the present disclosure, it should be noted that to those skilled in the art without departing from the technical theory of the present disclosure, can further make many changes and modifications, and the changes and the modifications should be considered as the scope of protection of the present disclosure.

What is claimed is:

1. A surface light source chip, comprising: a sapphire substrate, an N-type GaN buffer layer under the sapphire substrate, and a chip positive electrode area and a chip negative electrode area formed under the N-type GaN buffer layer, wherein the chip positive electrode area comprises an N-type GaN layer, an multiple quantum well (MQW) light emitting layer, an omni-directional reflector (ODR) layer and a chip positive electrode arranged from top to bottom sequentially, wherein the chip negative electrode area comprises a chip negative electrode.

2. The surface light source chip as claimed in claim 1, wherein the ODR layer comprises a semiconductor material layer, a refracting layer, and a metal layer arranged from top to bottom sequentially.

3. The surface light source chip as claimed in claim 2, wherein the semiconductor material layer is a GaN layer.

4. The surface light source chip as claimed in claim 2, wherein the refracting layer is an indium tin oxide (ITO) layer or a microporous oxide thin film.

5. The surface light source chip as claimed in claim 4, wherein a thickness of the refracting layer satisfies λ/(4n), wherein A is a wavelength and n is a refractive index of the refracting layer.

6. The surface light source chip as claimed in claim 2, wherein the metal layer is electrically conductive material, comprising an alloy of gold and nickel or a silver metal.

7. The surface light source chip as claimed in claim 1, wherein under the chip positive electrode is a positive metal electrode pad, and under the chip negative electrode is a negative metal electrode pad.

8. A light emitting diode, which comprises a plurality of surface light source chips each are as claimed in claim 1.

9. The light emitting diode as claimed in claim 8 further comprising:
a substrate which is used to carry the surface light source chips;
a fluorescent thin film which covers the substrate and the surface light source chips.

10. The light emitting diode as claimed in claim 9, wherein the surface light source chips are disposed on the substrate with an equal spacing there among.
